(19) United States
(12) Patent Application Publication
(10) Pub. No.: US 2022/0040735 A1
(43) Pub. Date: Feb. 10, 2022

(54) DUAL LAYER ULTRASONIC TRANSDUCER FABRICATION PROCESS

(71) Applicant: TDK Corporation, Tokoyo (JP)

(72) Inventor: Chienliu CHANG, Los Altos, CA (US)

(73) Assignee: TDK Corporation, Tokoyo (JP)

(21) Appl. No.: 17/390,732

(22) Filed: Jul. 30, 2021

Related U.S. Application Data
(60) Provisional application No. 63/062,281, filed on Aug. 6, 2020.

(51) Int. Cl. B06B 1/06; H01L 41/047; H01L 41/053; H01L 41/08; H01L 41/083; H01L 41/23; H01L 41/277; H01L 41/319; H01L 41/332

(52) U.S. Cl. CPC B06B 1/0611; H01L 41/0471; H01L 41/0533; H01L 41/0815; H01L 41/332; H01L 41/23; H01L 41/277; H01L 41/319; H01L 41/0838

(57) ABSTRACT

An array of piezoelectric micromachined ultrasonic transducers (PMUTs) includes a first piezoelectric layer and a second piezoelectric layer, a dielectric layer positioned between the first piezoelectric layer and the second piezoelectric layer, and a plurality of conductive layers positioned on opposing surfaces of the first piezoelectric layer and opposing surfaces of the second piezoelectric layer. A plurality of isolation trenches extend through the dielectric layer and at least a portion of conductive layers of the plurality of conductive layers, where the plurality of isolation trenches are positioned between neighboring PMUTs of the array of PMUTs such that the neighboring PMUTs are electrically isolated, and wherein the plurality of isolation trenches relieve stress in the dielectric layer.

### RELATED APPLICATIONS

This application claims priority to and the benefit of co-pending U.S. Patent Provisional Patent Application 63/062,281, filed on Aug. 6, 2020, entitled “DUAL LAYER ULTRASONIC TRANSDUCER FABRICATION PROCESS,” by Chienliu Chang, having Attorney Docket No. IVS-969-PR, and assigned to the assignee of the present application, which is incorporated herein by reference in its entirety.

### BACKGROUND

Piezoelectric materials facilitate conversion between mechanical energy and electrical energy. Moreover, a piezoelectric material can generate an electrical signal when subjected to mechanical stress, and can vibrate when subjected to an electrical voltage. Piezoelectric materials are widely utilized in piezoelectric ultrasonic transducers to generate acoustic waves based on an actuation voltage applied to electrodes of the piezoelectric ultrasonic transducer.

### BRIEF DESCRIPTION OF THE DRAWINGS

The accompanying drawings, which are incorporated in and form a part of the Description of Embodiments, illustrate various embodiments of the subject matter and, together with the Description of Embodiments, serve to explain principles of the subject matter discussed below. Unless specifically noted, the drawings referred to in this Brief Description of Drawings should be understood as not being drawn to scale. Herein, like items are labeled with like item numbers.

FIG. 1 is a diagram illustrating a dual layer ultrasonic transducer device having a buffer layer between the two piezoelectric layers, according to some embodiments.

FIG. 2A is a diagram illustrating an example transmit operation of a dual layer ultrasonic transducer device having a buffer layer between the two piezoelectric layers, according to some embodiments.

FIG. 2B is a diagram illustrating an example receive operation of a dual layer ultrasonic transducer device having a buffer layer between the two piezoelectric layers, according to some embodiments.

FIG. 3 is a diagram illustrating a dual layer ultrasonic transducer device having a buffer layer between the two piezoelectric layers and an interior support structure coupled to the substrate and the membrane, according to some embodiments.

FIGS. 4A through 4D illustrate example electrode configurations of a membrane dual layer ultrasonic transducer device having a buffer layer between the two piezoelectric layers during transmit and receive operations, according to some embodiments.

FIGS. 5A through 5G illustrate example steps in a fabrication process for a dual layer ultrasonic transducer device having a buffer layer between the two piezoelectric layers, according to some embodiments.

FIGS. 5H through 5O illustrate example steps in a fabrication process for a dual layer ultrasonic transducer device having a buffer layer between the two piezoelectric layers, in which the electrodes on both sides of the buffer layer are connected to different terminals, according to some embodiments.

FIGS. 6A through 6H illustrate example steps in a fabrication process for a dual layer ultrasonic transducer device having a buffer layer between the two piezoelectric layers, in which the electrodes on both sides of the buffer layer are connected to the same terminal and operate as a single electrode, according to some embodiments.

### DESCRIPTION OF EMBODIMENTS

The following Description of Embodiments is merely provided by way of example and not of limitation. Furthermore, there is no intention to be bound by any expressed or implied theory presented in the preceding background or in the following Description of Embodiments.

Reference will now be made in detail to various embodiments of the subject matter, examples of which are illustrated in the accompanying drawings. While various embodiments are discussed herein, it will be understood that they are not intended to limit to these embodiments. On the contrary, the presented embodiments are intended to cover alternatives, modifications and equivalents, which may be included within the spirit and scope the various embodiments as defined by the appended claims. Furthermore, in this Description of Embodiments, numerous specific details are set forth in order to provide a thorough understanding of embodiments of the present subject matter. However, embodiments may be practiced without these specific details. In other instances, well known methods, procedures, components, and circuits have not been described in detail as not to unnecessarily obscure aspects of the described embodiments.

### Overview of Discussion

Microelectromechanical systems (MEMS) may refer to a class of structure or devices fabricated using semiconductor-like processes and exhibiting mechanical characteristics such as the ability to move or deform. MEMS often, but not always interact with electrical signals. Fingerprint sensing through MEMS devices may be achieved through an array of piezoelectric micromachined ultrasound transducer (PMUT) devices. The general principle of these devices is that they transmit ultrasonic waves which may interact with object position on or close to the device, such as a fingerprint sensor interacting with the end of a finger. By detecting and analyzing the reflected waves, characteristics of the object can be determined. In the case of an ultrasonic fingerprint sensor, the sensor may be used to acquire a fingerprint image of a finger pressed on the sensor. PMUT devices may have additional applications in any suitable application wherein ultrasonic signals may be used to identify physical characteristics of interest (e.g., medical imaging, where an image of a biometric surface may be captured by an array of PMUT devices). In this manner, an array of PMUT devices may be operated at a suitable power and frequency to generate ultrasonic signals suitable for providing ultrasonic signals to a region of interest, receiving reflections of those signals, and generating a composite image based on the reflected signals.

A PMUT array may be fabricated according to semiconductor manufacturing processes as numerous PMUT devices arranged in a suitable pattern for a particular end-use application (e.g., dozens of PMUT devices arranged adjacent to each other to perform fingerprint sensing). The adjacent PMUT devices of a PMUT array are fabricated simultaneously as a substrate (e.g., a wafer) that progresses sequentially through processing operations such as deposition, doping, patterning, etching, and other standard operations.

An example MEMS PMUT device comprises a number of layers, including at least one piezoelectric layer of a material that generates a mechanical response to an applied electrical signal (e.g., to generate a desired ultrasonic output signal) and an electrical signal in response to an applied mechanical force (e.g., from a received reflected ultrasonic signal). The PMUT device may also include a processing layer that includes signal paths and signal processing circuitry (e.g., amplifiers, filters, etc.) for providing and receiving the electrical signals to and from the piezoelectric layer. In order to generate the desired ultrasonic output and to process the received reflections, it may be desirable for the piezoelectric layer to be a relatively thick layer within the PMUT device and to extend over most of the planar area of the PMUT device. For example, a high stiffness of the vibrating membrane may provide a restoring force after electrical actuation at a certain frequencies within ultrasonic propagation ranges. Electrical signals are applied to and received from the piezoelectric layer by electrodes on opposite sides of the piezoelectric layer. One of the electrodes may be fabricated at a point of the process at which it can be selectively patterned such that an electrical connection can extend between the processing layer (e.g., to and/or from an amplifier of the processing layer) while the second electrode may be fabricated as a conductive plane layer at a stage of the process that makes patterning more difficult. A via through a portion of the piezoelectric layer may be required to provide an electrical connection between the processing layer (e.g., a second amplifier of the processing layer) and the second electrode.

Embodiments described herein relate to a dual layer ultrasonic transducer for ultrasonic wave generation and sensing. In accordance with various embodiments, the ultrasonic transducer device includes a substrate, an edge support structure connected to the substrate, and a membrane connected to the edge support structure such that a cavity is defined between the membrane and the substrate, the membrane configured to allow movement at ultrasonic frequencies. The membrane includes a first piezoelectric layer having a first surface and a second surface, a second piezoelectric layer having a first surface and a second surface, wherein the second surface of the first piezoelectric layer faces the first surface of the second piezoelectric layer, a first electrode coupled to the first surface of the first piezoelectric layer, a second electrode coupled to the second surface of the second piezoelectric layer, and a third electrode between the first piezoelectric layer and the second piezoelectric layer.

### Dual Layer Ultrasonic Transducer

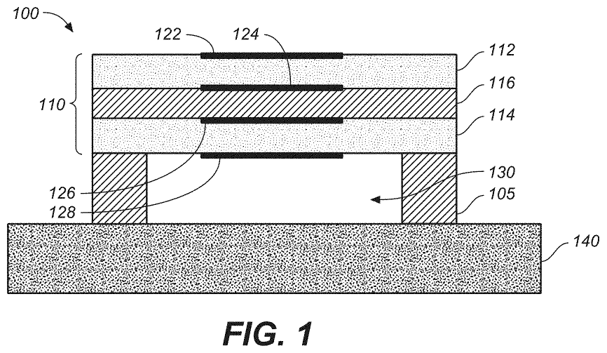

FIG. 1 is a diagram illustrating a dual layer ultrasonic transducer device 100 having a buffer layer between the two piezoelectric layers, according to some embodiments. Dual layer ultrasonic transducer device 100 includes a membrane 110 positioned over a substrate 140 to define a cavity 130. In one embodiment, membrane 110 is attached to a surrounding edge support 105. In one embodiment, edge support 105 is connected to an electric potential for connecting to electrodes 122, 124, 126, and/or 128. Edge support 105 may be made of electrically conducting materials, such as and without limitation, aluminum, molybdenum, or titanium. Edge support 105 may also be made of dielectric materials, such as silicon dioxide, silicon nitride or aluminum oxide that have electrical connections along the sides or in vias through edge support 105, for electrically coupling electrode 122, 124, 126, and/or 128 to electrical wiring in substrate 140. For example, substrate 140 may include terminals for electrically coupling electrodes 122, 124, 126, and/or 128 to control circuitry.

In various embodiments, substrate 140 may include at least one of, and without limitation, silicon or silicon nitride. It should be appreciated that substrate 140 may include electrical wirings and connection, such as aluminum or copper. In one embodiment, substrate 140 includes a CMOS logic wafer bonded to edge support 105. In one embodiment, the membrane 110 comprises buffer layer 116 positioned between piezoelectric layers 112 and 114. In an example embodiment, the membrane 110 includes piezoelectric layers 112 and 114, and electrodes 122, 124, 126, and/or 128, with electrodes 122 and 124 on opposing sides of piezoelectric layer 112 and electrodes 126 and 128 on opposing sides of piezoelectric layer 114, and buffer layer 116 between electrodes 124 and 126. While embodiments described herein are directed toward a dual layer ultrasonic transducer device including two piezoelectric layers, it should be appreciated that the principles described herein allow for the use of more than two piezoelectric layers, and that in some conceivable embodiments a multi-layer ultrasonic transducer device including more than two piezoelectric layers may be utilized. It should be appreciated that, in various embodiments, dual ultrasonic transducer device 100 is a microelectromechanical (MEMS) device. In accordance with various embodiments, piezoelectric layers 112 and 114 and buffer layer 116 have thicknesses in the range of one to ten microns. For example, piezoelectric layers 112 and 114 have a thickness of one micron and buffer layer 116 have thickness of two microns, such that membrane 110 has a thickness of four microns).

It should be appreciated that, dual layer ultrasonic transducer device 100 (and membrane 110) can be one of many types of geometric shapes (e.g., ring, circle, square, octagon, hexagon, etc.). For example, a sensing device may include an array of dual layer ultrasonic transducer devices 100. In some embodiments, the dual layer ultrasonic transducer devices 100 can be of a shape that allows for close adjacent placement of dual layer ultrasonic transducer devices 100. In some embodiments, adjacent dual layer ultrasonic transducer devices 100 within an array may share edge support structures 105. In other embodiments, adjacent dual layer ultrasonic transducer devices 100 within an array are electrically and physically isolated from each other (e.g., separated by a gap or isolation trench).

It should be appreciated that in accordance with various embodiments, membrane 110 can also include other layers (not shown), such a mechanical support layer, e.g., stiffening layer, and an acoustic coupling layer. The mechanical support layer is configured to mechanically stiffen the layers of membrane 110. The mechanical support layer can be above or below membrane 110. In various embodiments, the mechanical support layer may include at least one of, and without limitation, silicon, silicon oxide, silicon nitride, aluminum, molybdenum, titanium, etc. The acoustic coupling layer is for supporting transmission of acoustic signals, and, if present, is above membrane 110. It should be appreciated that acoustic coupling layer can include air, liquid, gel-like materials, or other materials for supporting transmission of acoustic signals.

In some embodiments, a plurality of dual layer ultrasonic transducer devices 100 are comprised within a two-dimensional (or one-dimensional) array of dual layer ultrasonic transducer devices. In such embodiments, the array of dual layer ultrasonic transducer devices 100 may be coupled to a platen layer above an acoustic coupling layer for containing the acoustic coupling layer and providing a contact surface for a finger or other sensed object with the array of dual layer ultrasonic transducer devices 100. It should be appreciated that, in various embodiments, the acoustic coupling layer provides a contact surface, such that a platen layer is optional. It should be appreciated that the contact surface can be flat or of a varying thickness (e.g., curved).

The described dual layer ultrasonic transducer device 100 is capable of generating and receiving ultrasonic signals. An object in a path of the generated ultrasonic signals can create a disturbance (e.g., changes in frequency or phase, reflection signal, echoes, etc.) that can then be sensed. The interference can be analyzed to determine physical parameters such as (but not limited to) distance, density and/or speed of the object. As an example, the dual layer ultrasonic transducer device 100 can be utilized in various applications, such as, but not limited to, fingerprint or physiologic sensors suitable for wireless devices, industrial systems, automotive systems, robotics, telecommunications, security, medical devices, etc. For example, the dual layer ultrasonic transducer device 100 can be part of a sensor array comprising a plurality of ultrasonic transducers deposited on a wafer, along with various logic, control and communication electronics. A sensor array may comprise homogenous or identical dual layer ultrasonic transducer devices 100, or a number of different or heterogonous device structures.

In various embodiments, the dual layer ultrasonic transducer device 100 employs piezoelectric layers 112 and 114, comprised of materials such as, but not limited to, aluminum nitride (AlN), scandium doped aluminum nitride (ScAlN), lead zirconate titanate (PZT), quartz, polyvinylidene fluoride (PVDF), and/or zinc oxide, to facilitate both acoustic signal production (transmitting) and sensing (receiving). The piezoelectric layers 112 and/or 114 can generate electric charges under mechanical stress and conversely experience a mechanical strain in the presence of an electric field. For example, piezoelectric layers 112 and/or 114 can sense mechanical vibrations caused by an ultrasonic signal and produce an electrical charge at the frequency (e.g., ultrasonic frequency) of the vibrations. Additionally, piezoelectric layers 112 and/or 114 can generate an ultrasonic wave by vibrating in an oscillatory fashion that might be at the same frequency (e.g., ultrasonic frequency) as an input current generated by an alternating current (AC) voltage applied across the piezoelectric layers 112 and/or 114. It should be appreciated that piezoelectric layers 112 and 114 can include almost any material (or combination of materials) that exhibits piezoelectric properties. The polarization is directly proportional to the applied stress and is direction dependent so that compressive and tensile stresses results in electric fields of opposite polarizations.

Buffer layer 116 separates piezoelectric layers 112 and 114. Buffer layer 116 can be comprised of dielectric materials such as, but not limited to, silicon, silicon oxide, polysilicon, silicon nitride, or any non-conducting oxide layer (or stacks of layers). Moreover, it should be appreciated that the buffer material can be application specific, e.g., selected based on a desired frequency of operation of dual layer ultrasonic transducer device 100. For example, buffer layer 116 can be a metal. It should be appreciated that the stiffer the material of buffer layer 116, the higher the frequency.

Buffer layer 116 allows for improved tuning of the transmit and receive operations, by enhancing the performance of the transmit and receive operations. The frequency can be tuned according to thickness of buffer layer 116 so as to optimize the thicknesses of piezoelectric layers 112 and 114 to improve the figure of merit (FOM) of dual layer ultrasonic transducer device 100. Moreover, the neutral axis can be designed to not be in the middle of membrane 110 so as to achieve a better FOM. Buffer layer 116 also supports tuning of the thicknesses and materials of piezoelectric layers 112 and 114.

Further, dual layer ultrasonic transducer device 100 comprises electrodes 122, 124, 126, and 128 that supply and/or collect the electrical charge to/from piezoelectric layers 112 and 114. Electrodes 122, 124, 126, and 128 can be connected to substrate 140 or the underlying circuitry via one or more terminals on substrate 140. Depending on the mode of operation, two or more electrodes may share a single terminal. It should be appreciated that electrodes 122, 124, 126, and 128 can be continuous and/or patterned electrodes (e.g., in a continuous layer and/or a patterned layer). As an example, electrodes 122, 124, 126, and 128 can be comprised of almost any metal layers, such as, but not limited to, aluminum (Al), titanium (Ti), Molybdenum (Mo), etc.

In accordance with various embodiments, electrodes 122, 124, 126, and/or 128 can be patterned in particular shapes (e.g., ring, circle, square, octagon, hexagon, etc.) that are defined in-plane with the membrane 110. Electrodes 122, 124, 126, and 128 can be placed at a maximum strain area of the membrane 110 or placed close to edge support 105. Furthermore, in one example, electrode 122 and/or 128 can be formed as a continuous layer providing a ground plane or other potential and electrode 124 and/or 126 can be formed as a continuous layer in contact with a mechanical support layer (not shown), which can be formed from silicon or other suitable mechanical stiffening material. In still other embodiments, the electrodes 122, 124, 126, and/or 128 can be routed along edge support 105. For example, when actuation voltage is applied to the electrodes, the membrane 110 will deform and move out of plane. The motion results in generation of an acoustic (ultrasonic) wave.

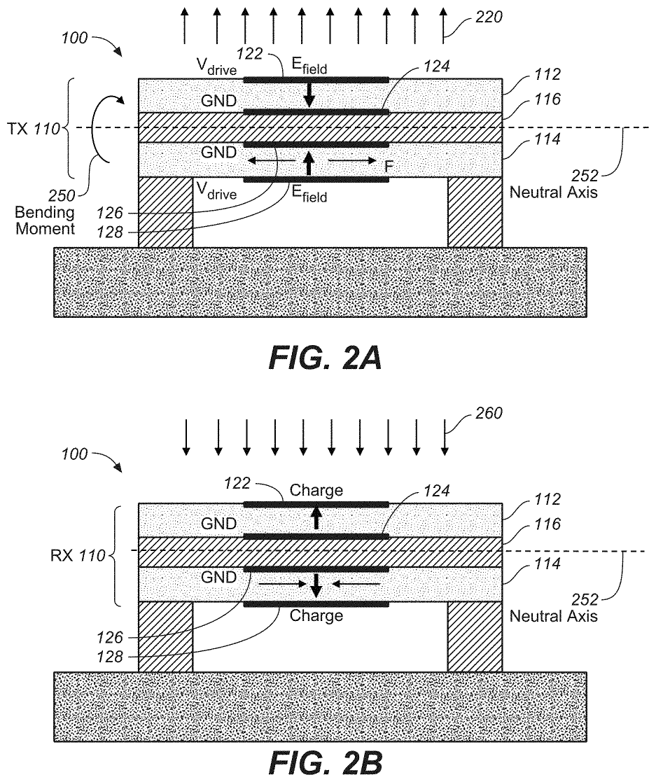

In some embodiments, electrodes 124 and 128 are coupled to a same terminal and operate as a single electrode, where electrodes 122 and 128 are coupled to ground (GND). FIG. 2A is a diagram illustrating an example transmit operation of a dual layer ultrasonic transducer device 100 having buffer layer 116 between piezoelectric layers 112 and 114, according to some embodiments. In some embodiments, during the transmit operation, piezoelectric layer 112 and piezoelectric layer 114 are driven using the same drive voltage (V_{drive}) causing opposing electric fields (E_{field}) toward electrode 124 from electrode 122 and toward electrode 126 from electrode 128 to generate an ultrasonic signal (illustrated as arrows 220). Applying the drive voltage to electrode 122 and electrode 128 also causes bending moment 250 about neutral axis 252. The use of buffer layer 116 provides for an increase the bending moment 250 by increasing the mechanical leverage from a piezoelectric center to the neutral axis 252. For instance, piezoelectric layers 112 and 114 are driven with electric fields in opposing directions, causing double the force (F) and double the deformation of a single piezo electric layer, resulting in doubling the pressure with respect to a single piezoelectric layer driven using the same drive voltage. In other embodiments, at least one of electrode pair 122 and 124 and electrode pair 128 and 126 can be used to provide a differential drive mode.

FIG. 2B is a diagram illustrating an example receive operation of a dual layer ultrasonic transducer device 100 having buffer layer 116 between piezoelectric layers 112 and 114, according to some embodiments. In some embodiments, during the receive operation, the deformation of membrane 110 is induced by the incoming pressure (illustrated as arrows 260), causing charge to be collected at electrode 122 and electrode 128. For instance, electrode 122 and electrode 128 both receive charge, resulting in doubling the charge collected with respect to a single piezoelectric layer responsive to the same incoming pressure. Moreover, doubling the receive capacitance relative to a single piezoelectric layer makes dual layer ultrasonic transducer device 300 more robust to parasitic capacitance loss than a single layer ultrasonic transducer device. In other embodiments, at least one of electrode pair 122 and 124 and electrode pair 128 and 126 can be used to provide a differential sense mode.

In some embodiments, electrodes 122 and 128 are coupled to different terminals and operate as separate electrodes, where electrodes 124 and 126 are coupled to ground (GND). For instance, piezoelectric layer 112 and electrodes 122 and 124 can be used during one of a receive or transmit operation, and piezoelectric layer 114 and electrodes 126 and 128 can be used during the other operation (e.g., piezoelectric layer 112 used for the transmit operation and piezoelectric layer 114 used for the receive operation, or vice versa).

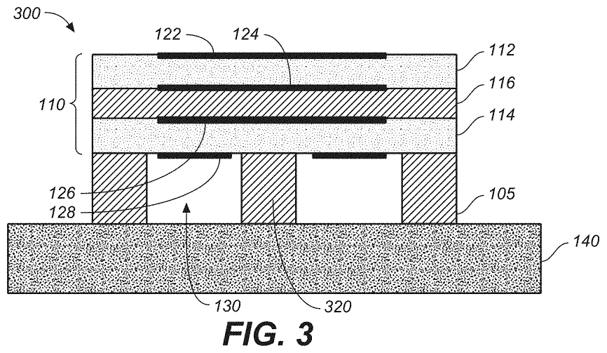

FIG. 3 is a diagram illustrating a dual layer ultrasonic transducer device 300 having a buffer layer 116 between piezoelectric layers 112 and 114, and an interior support 320 coupled to substrate 140 and membrane 110, according to some embodiments. Dual layer ultrasonic transducer device 300 operates in a similar manner, and includes the same configuration, as dual layer ultrasonic transducer device 100 of FIG. 1, apart from the addition of interior support 320.

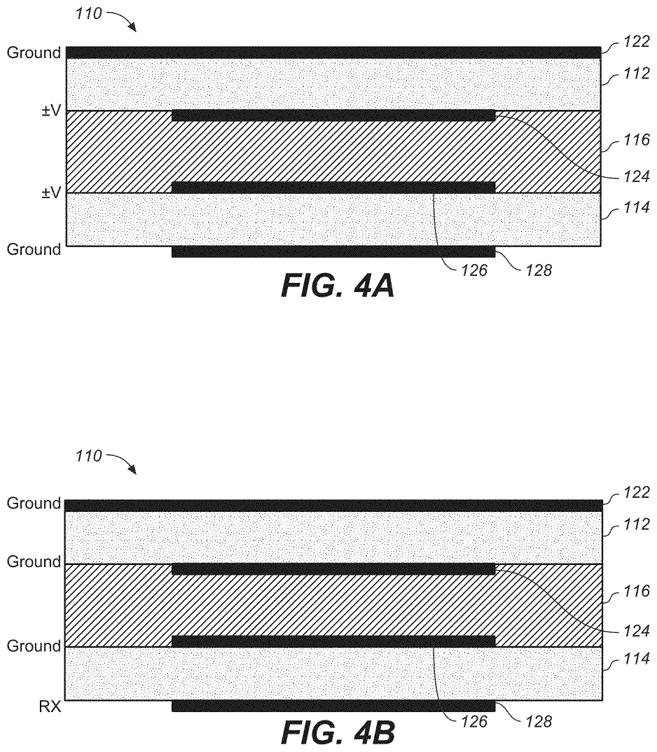

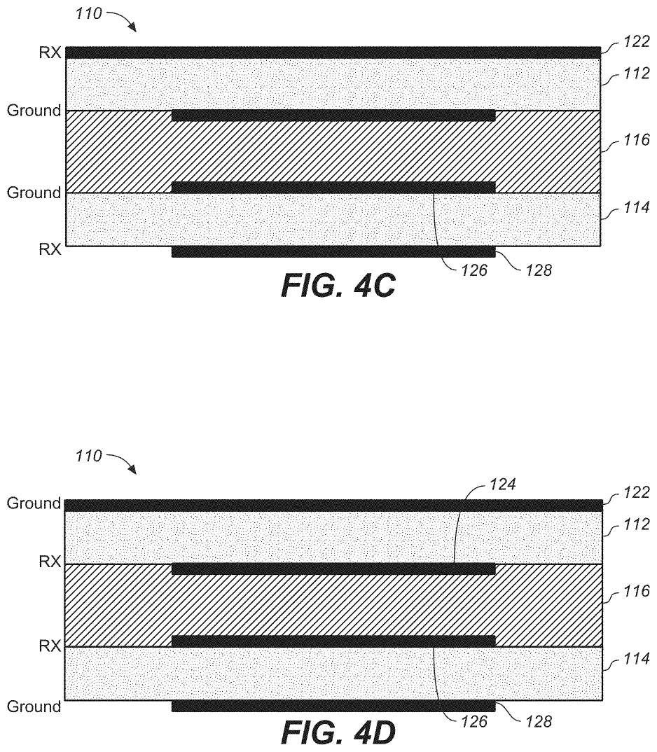

FIGS. 4A through 4D illustrate example electrode configurations of a membrane 110 of a dual layer ultrasonic transducer device having a buffer layer between the two piezoelectric layers during transmit and receive operations, according to some embodiments. As shown in the illustrated examples, piezoelectric layers 112 and 114 comprise aluminum nitride (AlN), buffer layer 116 comprises silicon dioxide (SiO₂), electrodes 122, 124, and 126 comprise Molybdenum (Moly), and electrode 128 comprises aluminum (Al). As presented above, it should be appreciated that other materials may be used in piezoelectric layers 112 and 114, buffer layer 116, and electrodes 122, 124, 126, and 128, of which the illustrated embodiments are examples.

FIG. 4A illustrates an electrode configuration used during an example transmit operation in which electrodes 122 and 128 are coupled to ground and electrodes 124 and 126 are coupled to a drive voltage, resulting in the generation of an ultrasonic signal.

FIG. 4B illustrates an electrode configuration used during an example receive operation in which electrodes 122, 124, and 126 are coupled to ground and electrode 128 is configured to receive a charge in response to incoming pressure, resulting in the charge being collected at electrode 128.

FIG. 4C illustrates an electrode configuration used during an example receive operation in which electrodes 124 and 126 are coupled to ground and electrodes 122 and 128 are configured to receive a charge in response to incoming pressure, resulting in the charge being collected at electrodes 122 and 128.

FIG. 4D illustrates an electrode configuration used during an example receive operation in which electrodes 122 and 128 are coupled to ground and electrodes 124 and 126 are configured to receive a charge in response to incoming pressure, resulting in the charge being collected at electrodes 124 and 126.

### Dual Layer Ultrasonic Transducer Fabrication Process

The following figures describe the different steps of the dual layer ultrasonic transducer fabrication process. The figures go through the process step by step. The order of the steps may be different then shown, some steps may be omitted or additional steps may be required, without diverting from the disclosed invention.

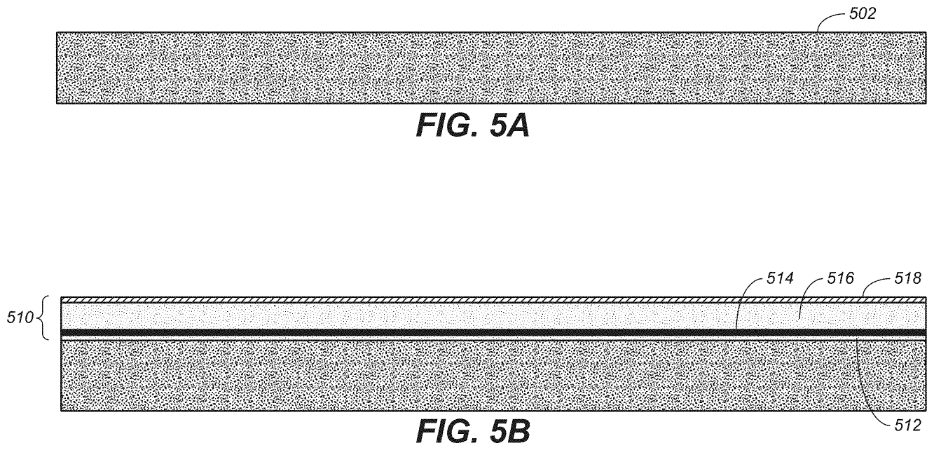

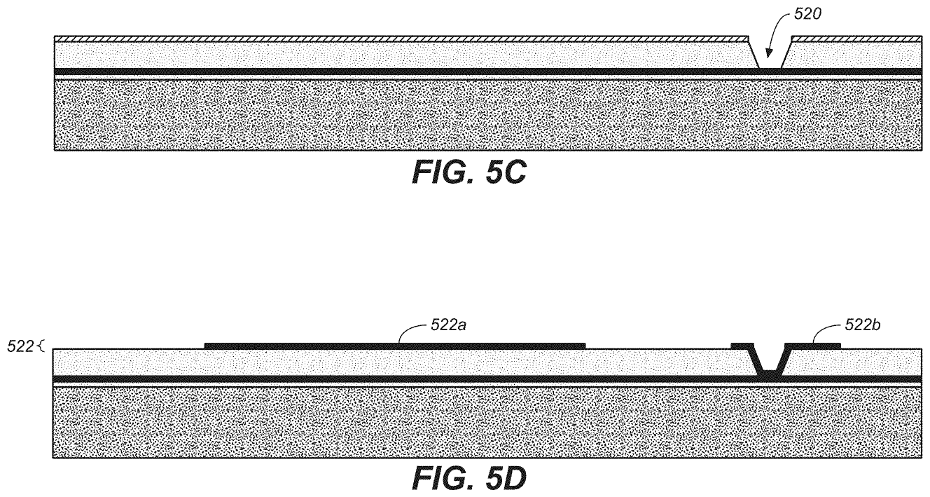

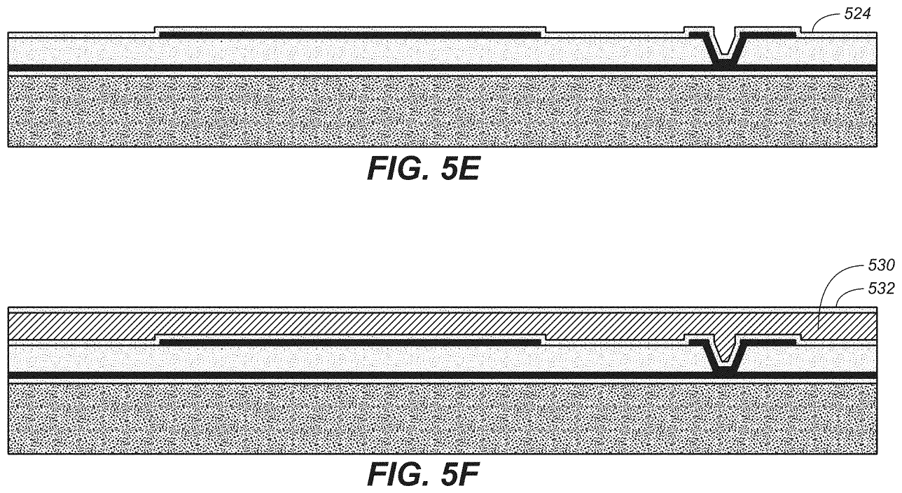

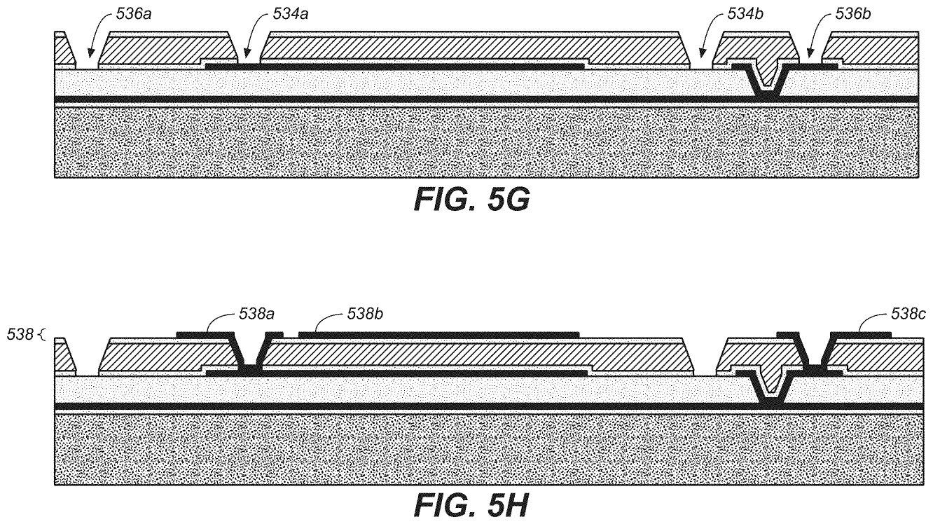

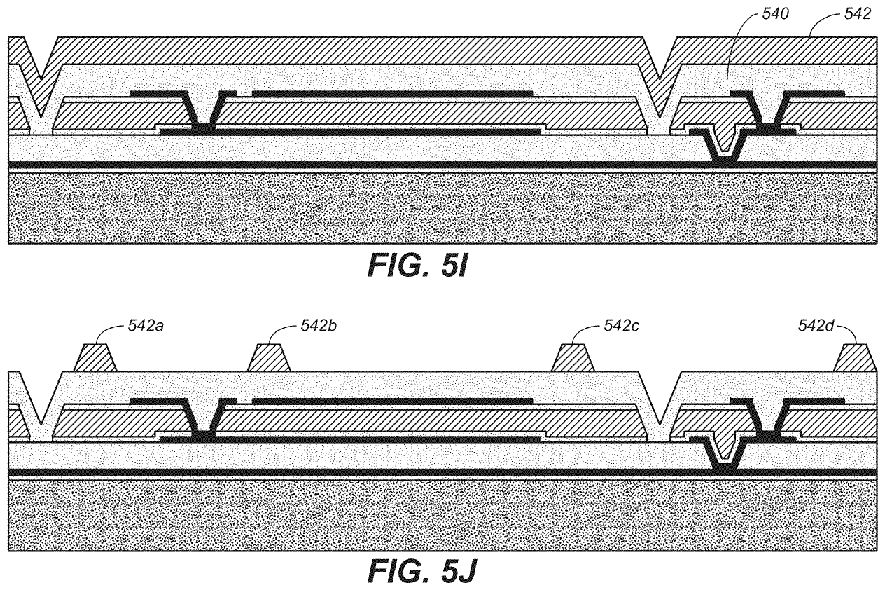

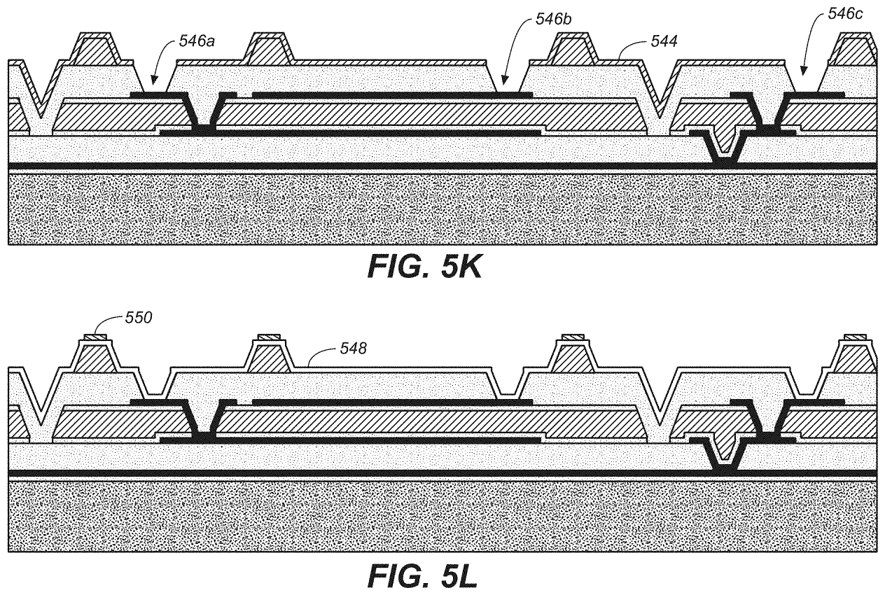

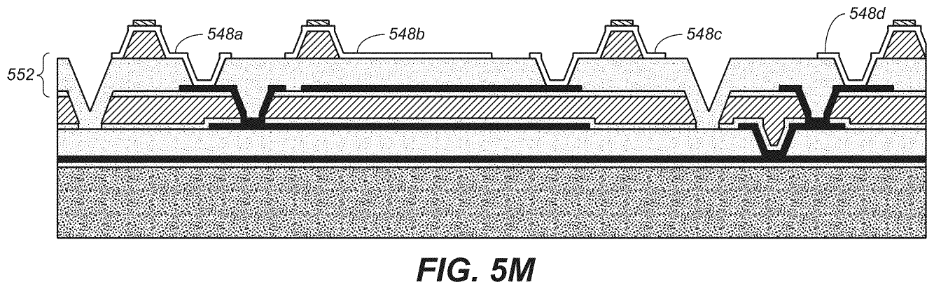

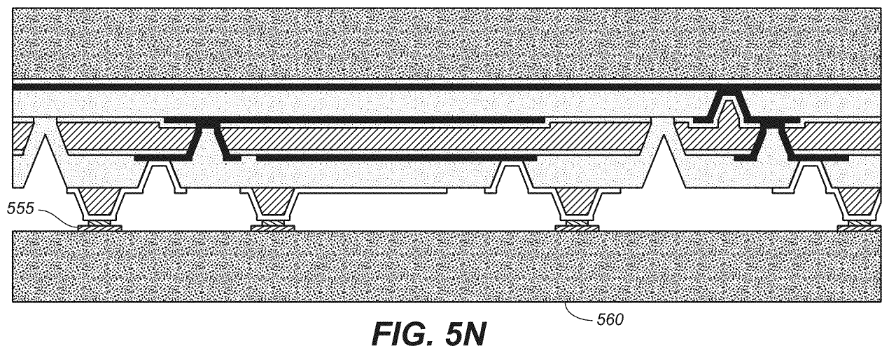

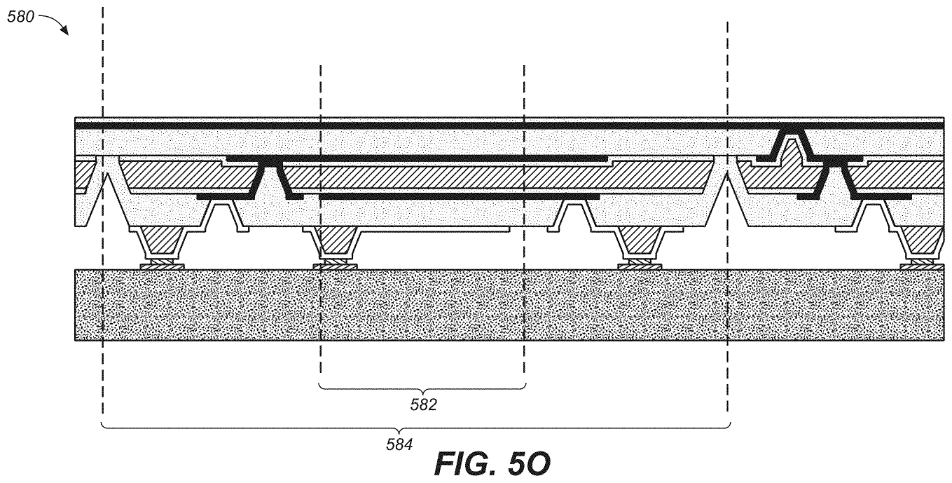

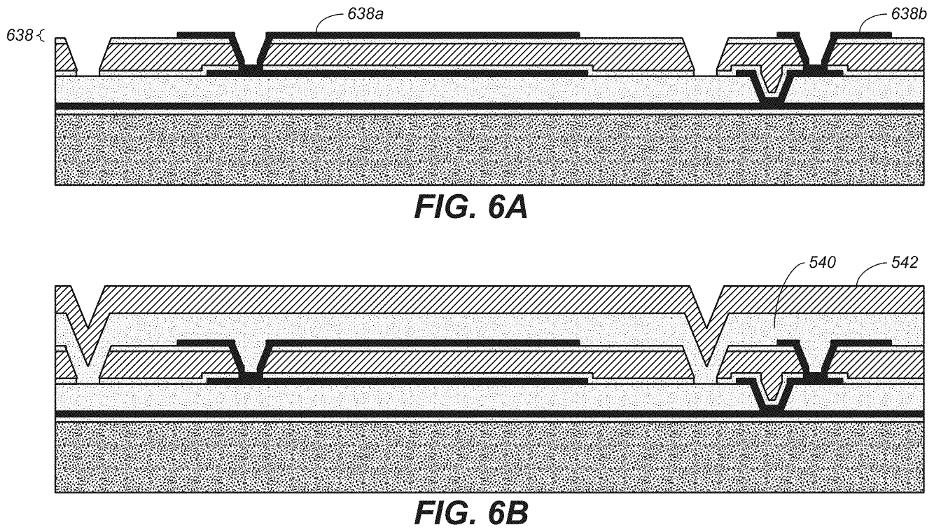

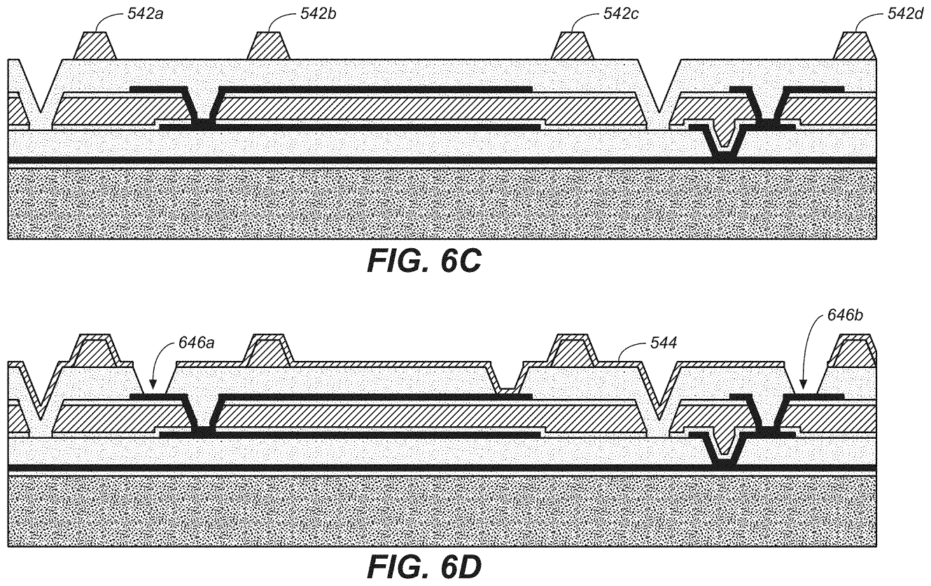

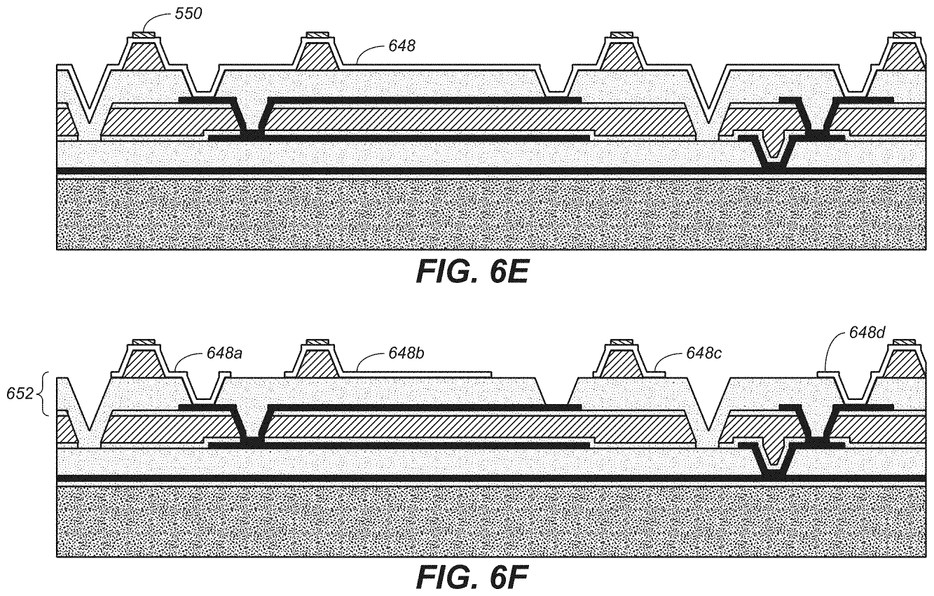

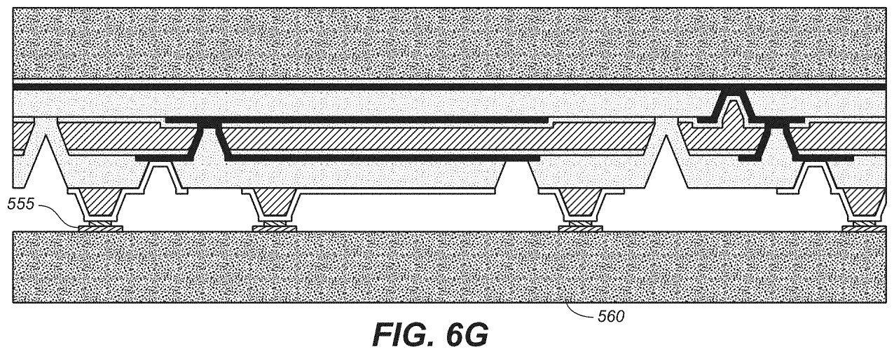

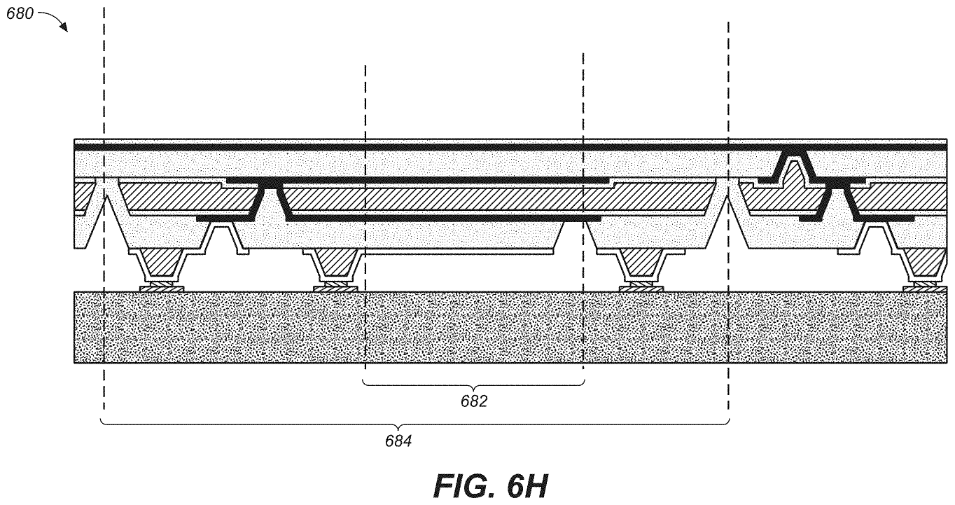

Two different process flows are described. In the first process flow, as shown at FIGS. 5A through 5O, the two electrodes around the central a buffer layer are connected to the same terminal. As a consequence, these electrodes will have the same voltage (change). In the second process flow, as shown at FIGS. 5A through 5G and FIGS. 6A through 6H, the two electrodes around the central a buffer layer are connected to separate terminals. As a consequence, these electrodes can have the different voltages or voltage changes. It should be appreciated that the process steps for both process flows are the same at FIGS. 5A through 5G. Accordingly, FIGS. 5G through 5O illustrate process steps associated with the first process flow and FIGS. 6A through 6H illustrate process steps associated with the second process flow, with FIGS. 5A through 5G being common to both process flows.

Specific materials are mentioned in the process flow step, but these materials are just examples. Any other suitable replacement material may be used. For example, aluminum nitride (AlN) as an example piezo material, but other materials such e.g., scandium doped aluminum nitride (ScAlN), MgZr doped aluminum nitride (MgZrAlN), lead zirconate titanate (PZT), quartz, polyvinylidene fluoride (PVDF), and/or zinc oxide. The dual piezo layer may also comprise different materials, for example to increase performance, or to select one material for transmit performance and the other material for receive performance. Specific dimensions or layer thickness are shown as examples. However, other thickness may also be used, and may even be one or more order of magnitude different. For example, AlN thicknesses of the order of 1 um are shown, but in variations of the invention, the thickness may be as small as 0.1 um or as large as 10 um. Similarly, an example SiO buffer layer thickness of the order of 2.3 um is shown, but in variations of the invention, the thickness may be as small as 0.1 um or as large as 10 um.

FIGS. 5A through 6H depict example process steps for fabricating an example dual layer PMUT device of the described embodiments, such as the example dual layer ultrasonic transducer device 100 device of FIG. 1. Although particular steps are depicted and described in a particular order, it will be understood that one or more steps may be omitted or added in accordance with the present disclosure. In some embodiments, different materials or combinations of materials may be utilized to perform similar functions, and a variety of suitable operations may be utilized for depositing, treating, doping, removing, bonding and otherwise processing the PMUT device.

FIG. 5A shows an example step of fabricating an example dual layer PMUT device having a buffer layer between two piezoelectric layers. At the step of FIG. 5A, a wafer 502 (e.g., a silicon wafer or a structural layer) is prepared for receiving various layer depositions.

FIG. 5B shows an example step of a first piezoelectric layer stack 510 deposition. At the step of FIG. 5B, a first seed layer 512 (e.g., an AlN seed layer) is deposited on wafer 502. In one example embodiment, the first seed layer 512 has a thickness of 0.1 um. A first conductive layer 514 (e.g., Mo) is deposited on first seed layer 512. In one example embodiment, first conductive layer 514 has a thickness 0.2 um. A first piezoelectric layer 516 (e.g., AlN) is deposited on first conductive layer 514. In one example embodiment, first piezoelectric layer 516 has a thickness of 1 um. It should be appreciated that, in accordance with various embodiments, first seed layer 512 has desired crystal structure such that first conductive layer 514 maintains a continuous crystal structure of first seed layer 512, allowing the deposition of first conductive layer 514 and first piezoelectric layer 516 to maintain the desired crystal structure.

In one embodiment, first isolation oxide layer 518 (e.g., SiO) is deposited on first piezoelectric layer 516. In one example embodiment, first isolation oxide layer 518 has a thickness of 0.1 um. First isolation oxide layer 518 can act as an edge mask for protecting first piezoelectric layer 516 during etching and during removal of residue after dry etching.

FIG. 5C shows an example step of etching via 520 within at least a portion of first piezoelectric stack 510. Via 520 is etched through first isolation oxide layer 518 (e.g., when present) and first piezoelectric layer 516 to expose first conductive layer 514. When present, first isolation oxide layer 518 is removed (e.g., using reactive ion etching) prior to commencing the example step of FIG. 5D.

FIG. 5D shows an example step of depositing second conductive layer 522 (e.g., Mo) on first piezoelectric layer 516 and the portion of first conductive layer 514 exposed through via 520, where first conductive layer 514 and second conductive layer 522 are electrically coupled. In one example embodiment, second conductive layer 522 has a thickness 0.2 um. Second conductive layer 522 is patterned, separating into electrode 522a and electrical connection 522b, such that electrical connection 522b remains electrically coupled to first conductive layer 514.

FIG. 5E shows an example step of depositing protective layer 524 (e.g., AlN) on electrode 522a, electrical connection 522b, and exposed portions of first piezoelectric layer 516. In some embodiments, protective layer 524 has a thickness of 0.2 um. Protective layer 524 operates to protect electrode 522a and electrical connection 522b during a subsequent dielectric deposition shown at FIG. 5F.

FIG. 5F shows an example step of depositing first dielectric layer 530 (e.g., SiO) on protective layer 524, where first dielectric layer 530 is a buffer layer between first piezoelectric layer stack 510 and a subsequently deposited second piezoelectric layer stack (e.g., second piezoelectric layer stack 552 of FIG. 5M and second piezoelectric layer stack 652 of FIG. 6F). In some embodiments, first dielectric layer 530 has a thickness of 1.5 um. It should be appreciated that, in accordance with one embodiment, first dielectric layer 530 may be deposited at a thickness greater than the desired final thickness, where the final thickness is achieved using a chemical mechanical polish (CMP).

At the step of FIG. 5F, a second seed layer 532 (e.g., an AlN seed layer) is deposited on first dielectric layer 530. In one example embodiment, second seed layer 532 has a thickness of 0.1 um. It should be appreciated that, in accordance with various embodiments, second seed layer 532 has desired crystal structure such that subsequently deposited layers can maintain the desired crystal structure of second seed layer 532.

FIG. 5G shows an example step of etching vias 534a and 534b within first dielectric layer 530 and second seed layer 532. Via 534a is etched through first dielectric layer 530 and second seed layer 532 to expose electrode 522a and via 534b is etched through first dielectric layer 530 and second seed layer 532 to expose electrical connection 522b.

FIG. 5G also shows an example step of etching isolation trenches 536a and 536b into first dielectric layer 530 and second seed layer 532 to at least first piezoelectric layer stack 510. In one embodiment, isolation trenches 536a and 536b are etched to expose first piezoelectric layer 516. Isolation trenches 536a and 536b are etched to electrically isolated neighboring dual layer PMUT devices (e.g., multiple dual layer PMUT devices are fabricated into an array of dual layer PMUT devices). Isolation trenches 536a and 536b release stress on first dielectric layer 530, which would otherwise be subject to causing different layers of the PMUT devices to peel and separate, thus negatively impacting performance of the PMUT devices.

In one embodiment, as presented above, FIGS. 5H through 5O illustrate the steps of the process flow where electrodes on both sides of the buffer layer (e.g., electrodes 522a and 538b on both sides of first dielectric layer 530) are connected to different terminals, and thus may be subject to different voltages. As such, electrodes 522a and 538b operate as separate and independent electrodes. It should be appreciated that, in accordance with some embodiments, electrodes 522a and 538b may be connected to or controlled by a switchable control for switching between a two terminal mode operating electrodes 522a and 538b as separate electrodes and a one terminal mode operating electrodes 522a and 538b as a single electrode.

FIG. 5H shows an example step of depositing third conductive layer 538 (e.g., Mo) on second seed layer 532, the portion of electrode 522a exposed through via 534a, and the portion of electrical connection 522b exposed through via 534b. In one example embodiment, third conductive layer 538 has a thickness 0.2 um. Third conductive layer 538 is patterned, separating into electrical connection 538a, electrode 538b, and electrical connection 538c, such that electrical connection 538a remains electrically coupled to electrode 522a and electrical connection 538c remains electrically coupled to electrical connection 522b.

FIG. 5I shows an example step of depositing second piezoelectric layer 540 (e.g., AlN) is deposited on electrical connection 538a, electrode 538b, electrical connection 538c, exposed portions of second seed layer 532, and exposed portions of first piezoelectric layer 516 through isolations trenches 536a and 536b. In one example embodiment, second piezoelectric layer 540 has a thickness of 1 um. It should be appreciated that, in accordance with various embodiments, second seed layer 532 has desired crystal structure such that electrical connection 538a, electrode 538b, and electrical connection 538c maintain a continuous crystal structure of first seed layer 512, allowing the deposition of third conductive layer 538 and second piezoelectric layer 540 to maintain the desired crystal structure.

FIG. 5I also shows an example step of depositing second dielectric layer 542 (e.g., SiO) over second piezoelectric layer 540. In one example embodiment, second dielectric layer 542 has a thickness of 2.3 um.

FIG. 5J shows an example step of patterning second dielectric layer 542 into standoffs 542a, 542b, 542c, and 542d.

FIG. 5K shows an example step of depositing second isolation oxide layer 544 (e.g., SiO) over second piezoelectric layer 540 and standoffs 542a, 542b, 542c, and 542d. In one example embodiment, second isolation oxide layer 544 has a thickness of 0.1 um. Second isolation oxide layer 544 is optionally deposited and can act as an edge mask for protecting second piezoelectric layer 540 during etching and during removal of residue after dry etching.

FIG. 5K also shows an example step of etching vias 546a, 546b, and 546c within second piezoelectric layer 540 and second isolation oxide layer 544 (e.g., when present). Via 546a is etched through second piezoelectric layer 540 and second isolation oxide layer 544 to expose electrical connection 538a, via 546b is etched through second piezoelectric layer 540 and second isolation oxide layer 544 to expose electrode 538b, and via 546c is etched through second piezoelectric layer 540 and second isolation oxide layer 544 to expose electrical connection 538c. When present, second isolation oxide layer 544 is removed (e.g., using reactive ion etching) prior to commencing the example step of FIG. 5L.

FIG. 5L shows an example step of depositing fourth conductive layer 548 (e.g., Al, Ti, and TiN) on second piezoelectric layer 540, the portion of electrical connection 538a exposed through via 546a, the portion of electrode 538b exposed through via 546b, and the portion of electrical connection 538c exposed through via 546c. In one example embodiment, fourth conductive layer 548 comprises multiple conductive materials deposited as separate layers. For example, fourth conductive layer 548 can include an aluminum (Al) layer (e.g., having a thickness of 0.3 um), a titanium (Ti) layer (e.g., having a thickness of 2 nm), and a titanium nitride (TiN) layer (e.g., having a thickness of 10.5 nm), where each layer is deposited successively. FIG. 5L also shows the deposition of pads 550 (e.g., germanium (Ge) pads having a thickness of 0.38 um) over the fourth conductive layer 548 and standoffs 542a, 542b, 542c, and 542d.

FIG. 5M shows an example step of patterning fourth conductive layer 548, separating fourth conductive layer 548 into electrical connection 548a, electrode 548b, electrical connection 548c, and electrical connection 548d, such that electrical connection 548a remains electrically coupled to electrical connection 538a, electrical connection 548c remains electrically coupled to electrode 538b, electrical connection 548d remains electrically coupled to electrical connection 538c. Third conductive layer 538 (e.g., electrical connection 538a, electrode 538b, electrical connection 538c, second piezoelectric layer 540, and fourth conductive layer 548 (e.g., electrical connection 548a, electrode 548b, electrical connection 548c, and electrical connection 548d) can be collectively referred to as second piezoelectric layer stack 552.

FIG. 5N shows an example step of bonding pads 550 to corresponding pads 555 of control substrate 560 (e.g., CMOS).

FIG. 5O shows an example step of removing wafer 502, exposing first seed layer 512, resulting in dual layer PMUT device 580 of an array of dual layer PMUT devices 580. In some embodiments, wafer 502 is removed using etching and or grinding. Dual layer PMUT device 580 is covers the area of region 584, while the active region of dual layer PMUT device 580 (e.g., where electrodes 522a, 538b, and 548b are active) is defined by region 582.

In one embodiment, as presented above, FIGS. 6A through 6H illustrate the steps of the process flow where electrodes on both sides of the buffer layer (e.g., electrodes 522a and 638a on both sides of first dielectric layer 530) are connected to the same terminal, and thus subject to the same voltages. As such, electrodes 522a and 638a operate as a single electrode.

FIG. 6A shows an example step of depositing third conductive layer 638 (e.g., Mo) on second seed layer 532, the portion of electrode 522a exposed through via 534a, and the portion of electrical connection 522b exposed through via 534b. In one example embodiment, third conductive layer 538 has a thickness 0.2 um. Third conductive layer 538 is patterned, separating into electrode 638a and electrical connection 638b, such that electrode 638a remains electrically coupled to electrode 522a (and effectively operates as a single electrode with electrode 522a) and electrical connection 638b remains electrically coupled to electrical connection 522b.

FIG. 6B shows an example step of depositing second piezoelectric layer 540 (e.g., AlN) is deposited on electrode 638a, electrical connection 638b, exposed portions of second seed layer 532, and exposed portions of first piezoelectric layer 516 through isolations trenches 536a and 536b. In one example embodiment, second piezoelectric layer 540 has a thickness of 1 um. It should be appreciated that, in accordance with various embodiments, second seed layer 532 has desired crystal structure such that electrode 638a and electrical connection 638b maintain a continuous crystal structure of first seed layer 512, allowing the deposition of third conductive layer 638 and second piezoelectric layer 540 to maintain the desired crystal structure.

FIG. 6B also shows an example step of depositing second dielectric layer 542 (e.g., SiO) over second piezoelectric layer 540. In one example embodiment, second dielectric layer 542 has a thickness of 2.3 um.

FIG. 6C shows an example step of patterning second dielectric layer 542 into standoffs 542a, 542b, 542c, and 542d.

FIG. 6D shows an example step of depositing second isolation oxide layer 544 (e.g., SiO) over second piezoelectric layer 540 and standoffs 542a, 542b, 542c, and 542d. In one example embodiment, second isolation oxide layer 544 has a thickness of 0.1 um. Second isolation oxide layer 544 is optionally deposited and can act as an edge mask for protecting second piezoelectric layer 540 during etching and during removal of residue after dry etching.

FIG. 6D also shows an example step of etching vias 646a and 646b within second piezoelectric layer 540 and second isolation oxide layer 544 (e.g., when present). Via 646a is etched through second piezoelectric layer 540 and second isolation oxide layer 544 to expose electrode 638a and via 646b is etched through second piezoelectric layer 540 and second isolation oxide layer 544 to expose electrical connection 638b. When present, second isolation oxide layer 544 is removed (e.g., using reactive ion etching) prior to commencing the example step of FIG. 6E.

FIG. 6E shows an example step of depositing fourth conductive layer 648 (e.g., Al, Ti, and TiN) on second piezoelectric layer 540, the portion of electrode 638a exposed through via 646a and the portion of electrical connection 638b exposed through via 646b. In one example embodiment, fourth conductive layer 648 comprises multiple conductive materials deposited as separate layers. For example, fourth conductive layer 648 can include an aluminum (Al) layer (e.g., having a thickness of 0.3 um), a titanium (Ti) layer (e.g., having a thickness of 2 nm), and a titanium nitride (TiN) layer (e.g., having a thickness of 10.5 nm), where each layer is deposited successively. FIG. 6E also shows the deposition of pads 550 (e.g., germanium (Ge) pads having a thickness of 0.38 um) over the fourth conductive layer 648 and standoffs 542a, 542b, 542c, and 542d.

FIG. 6F shows an example step of patterning fourth conductive layer 648, separating fourth conductive layer 648 into electrical connection 648a, electrode 648b, electrical connection 648c, and electrical connection 648d, such that electrical connection 648a remains electrically coupled to electrode 638a, electrical connection 648c is not connected to any portion of the other conductive layers, and electrical connection 648d remains electrically coupled to electrical connection 638b. Third conductive layer 638 (e.g., electrode 638a and electrical connection 638b), second piezoelectric layer 540, and fourth conductive layer 648 (e.g., electrical connection 648a, electrode 648b, electrical connection 648c, and electrical connection 648d) can be collectively referred to as second piezoelectric layer stack 652.

FIG. 6G shows an example step of bonding pads 550 to corresponding pads 555 of control substrate 560 (e.g., CMOS).

FIG. 6H shows an example step of removing wafer 502, exposing first seed layer 512, resulting in dual layer PMUT device 680 of an array of dual layer PMUT devices 680. In some embodiments, wafer 502 is removed using etching and or grinding. Dual layer PMUT device 680 is covers the area of region 684, while the active region of dual layer PMUT device 680 (e.g., where electrodes 522a, 638a, and 648b and first conductive layer 514 are active) is defined by region 682.

What has been described above includes examples of the subject disclosure. It is, of course, not possible to describe every conceivable combination of components or methodologies for purposes of describing the subject matter, but it is to be appreciated that many further combinations and permutations of the subject disclosure are possible. Accordingly, the claimed subject matter is intended to embrace all such alterations, modifications, and variations that fall within the spirit and scope of the appended claims.

Thus, the embodiments and examples set forth herein were presented in order to best explain various selected embodiments of the present invention and its particular application and to thereby enable those skilled in the art to make and use embodiments of the invention. However, those skilled in the art will recognize that the foregoing description and examples have been presented for the purposes of illustration and example only. The description as set forth is not intended to be exhaustive or to limit the embodiments of the invention to the precise form disclosed.

1. An array of piezoelectric micromachined ultrasonic transducers (PMUTs) comprising:
a first piezoelectric layer and a second piezoelectric layer;
a dielectric layer positioned between the first piezoelectric layer and the second piezoelectric layer;
a plurality of conductive layers positioned on opposing surfaces of the first piezoelectric layer and opposing surfaces of the second piezoelectric layer; and
a plurality of isolation trenches that extend through the dielectric layer and at least a portion of conductive layers of the plurality of conductive layers, wherein the plurality of isolation trenches are positioned between neighboring PMUTs of the array of PMUTs such that the neighboring PMUTs are electrically isolated, and wherein the plurality of isolation trenches relieve stress in the dielectric layer.

2. The array of PMUTs of claim 1, wherein the plurality of conductive layers comprises:
a first electrode coupled to a first surface of the first piezoelectric layer;
a second electrode coupled to a second surface of the first piezoelectric layer, wherein the second surface of the first piezoelectric layer is an opposite surface of the first piezoelectric layer than the first surface of the first piezoelectric layer, wherein the second surface of the first piezoelectric layer faces the dielectric layer;
a third electrode coupled to a first surface of the second piezoelectric layer, wherein the first surface of the second piezoelectric layer faces the dielectric layer; and
a fourth electrode coupled to a second surface of the second piezoelectric layer, wherein the second surface of the second piezoelectric layer is an opposite surface of the second piezoelectric layer than the first surface of the second piezoelectric layer.

3. The array of PMUTs of claim 2, further comprising:
a via in the first piezoelectric layer for providing a first electrical connection to the first electrode;
a first via in the dielectric layer for providing a first electrical connection to the second electrode;
a second via in the dielectric layer for providing a second electrical connection to the first electrode;
a first via in the second piezoelectric layer for providing an electrical connection to the third electrode;
a second via in the second piezoelectric layer for providing a second electrical connection to the second electrode; and
a third via in the second piezoelectric layer for providing a third electrical connection to the first electrode.

4. The array of PMUTs of claim 2, wherein the second electrode and the third electrode are coupled to a same terminal and operate as a single electrode.

5. The array of PMUTs of claim 4, further comprising:
a via in the first piezoelectric layer for providing a first electrical connection to the first electrode;
a first via in the dielectric layer for providing a first electrical connection to the second electrode and the third electrode;
a second via in the dielectric layer for providing a second electrical connection to the first electrode;
a first via in the second piezoelectric layer for providing a second electrical connection to the second electrode and the third electrode; and
a second via in the second piezoelectric layer for providing a third electrical connection to the first electrode.

6. The array of PMUTs of claim 1, further comprising:
a protective layer on a first surface of the dielectric layer, wherein the first surface of the dielectric layer faces the first piezoelectric layer.

7. The array of PMUTs of claim 1, further comprising:
a first seed layer on a second surface of the dielectric layer, wherein the second surface of the dielectric layer faces the second piezoelectric layer.

8. The array of PMUTs of claim 7, further comprising:
a second seed layer on a conductive layer of the plurality of conductive layers, wherein the conductive layer is on a first surface of the first piezoelectric layer, wherein the first surface of the first piezoelectric layer faces away from the dielectric layer.

9. The array of PMUTs of claim 1, further comprising:
a plurality of support structures coupled to the second piezoelectric layer and a conductive layer of the plurality of conductive layers.

10. A method for fabricating an array of piezoelectric micromachined ultrasonic transducers (PMUTs), the method comprising:
depositing a first piezoelectric stack over a structural layer, the first piezoelectric stack comprising a first conductive layer, a first piezoelectric layer over the first conductive layer, and a second conductive layer over the first piezoelectric layer;
depositing a first dielectric layer over the first piezoelectric stack;
etching a plurality of isolation trenches through the first dielectric layer, to at least the first piezoelectric stack, wherein the plurality of isolation trenches are positioned between neighboring PMUTs of the array of PMUTs such that the neighboring PMUTs are electrically isolated, and wherein the plurality of isolation trenches relieve stress in the first dielectric layer; and
depositing a second piezoelectric stack over the first dielectric layer, the second piezoelectric stack comprising a third conductive layer, a second piezoelectric layer over the third conductive layer, and a fourth conductive layer over the second piezoelectric layer.

11. The method of claim 10, wherein the depositing the first piezoelectric stack over the structural layer comprises:
depositing a first seed layer over the structural layer;
depositing the first conductive layer over the first seed layer; and
depositing the first piezoelectric layer over the first conductive layer.

12. The method of claim 11, wherein the depositing the first piezoelectric stack over the structural layer further comprises:
etching a via through the first piezoelectric layer at least to the first conductive layer.

13. The method of claim 12, wherein the etching the via through the first piezoelectric layer at least to the first conductive layer comprises:
depositing a first isolation oxide layer over the first piezoelectric layer.
etching the via through the first isolation oxide layer and the first piezoelectric layer at least to the first conductive layer; and
removing the first isolation oxide layer.

14. The method of claim 12, wherein the depositing the first piezoelectric stack over the structural layer further comprises:
depositing the second conductive layer over the first piezoelectric layer and exposed portions of the first conductive layer through the via in the first piezoelectric layer; and
patterning the second conductive layer.

15. The method of claim 14, further comprising:
depositing a protective layer over the second conductive layer and exposed portions of the first piezoelectric layer.

16. The method of claim 15, wherein the depositing the first dielectric layer over the first piezoelectric stack comprises:
depositing the first dielectric layer over the protective layer;
depositing a second seed layer over the first dielectric layer; and
etching a first via and a second via through the second seed layer, the first dielectric layer, and the protective layer to the second conductive layer.

17. The method of claim 16, wherein the depositing the second piezoelectric stack over the first dielectric layer comprises:
depositing the third conductive layer over the second seed layer and exposed portions of the second conductive layer through the first via and the second via in the first dielectric layer;
patterning the third conductive layer;
depositing a second piezoelectric layer over the third conductive layer, exposed portions of the second seed layer, and exposed portions of the first piezoelectric layer in the first via and the second via in the first dielectric layer;
depositing a second dielectric layer over the second piezoelectric layer; and
patterning the second dielectric layer to create a plurality of standoffs.

18. The method of claim 17, wherein the depositing the second piezoelectric stack over the first dielectric layer further comprises:
etching at least a first via and a second via through the second piezoelectric layer at least to the third conductive layer.

19. The method of claim 18, wherein the etching at least the first via and the second via through the second piezoelectric layer at least to the third conductive layer comprises:
depositing a second isolation oxide layer over the second piezoelectric layer and the plurality of standoffs;
etching at least the first via and the second via in the second piezoelectric layer through the second isolation oxide layer and the second piezoelectric layer at least to the third conductive layer; and
removing the second isolation oxide layer.

20. The method of claim 18, wherein the depositing the second piezoelectric stack over the first dielectric layer further comprises:
depositing a fourth conductive layer over the second piezoelectric layer, the plurality of standoffs, and exposed portions of the third conductive layer through the first via and the second via in the second piezoelectric layer; and
patterning the fourth conductive layer.

21. The method of claim 20, further comprising:
bonding the fourth conductive layer to a control substrate; and
removing the structural layer to expose the first seed layer.

22. The array of PMUTs of claim 1, wherein the first piezoelectric layer and the second piezoelectric layer are comprised of at least one of: aluminum nitride (AlN), scandium doped aluminum nitride (ScAlN), lead zirconate titanate (PZT), quartz, polyvinylidene fluoride (PVDF), and zinc oxide.
